(19) United States
(12) Patent Application Publication
(10) Pub. No.: US 2020/0235727 A1
(43) Pub. Date: Jul. 23, 2020

(54) SWITCHING ELEMENT DRIVE DEVICE

(71) Applicant: FUJI ELECTRIC CO., LTD., Kawasaki-shi (JP)

(72) Inventor: Masahiro TAOKA, Matsumoto-city (JP)

(73) Assignee: FUJI ELECTRIC CO., LTD., Kawasaki-shi (JP)

(21) Appl. No.: 16/691,793

(22) Filed: Nov. 22, 2019

(30) Foreign Application Priority Data
Jan. 17, 2019 (JP) 2019-005783

(51) Int. Cl. H03K 17/0412; H03K 17/16

(52) U.S. Cl. CPC H03K 17/0412; H03K 17/168

(57) ABSTRACT

A drive device for driving a switching element. The drive device includes a turn-on output transistor which supplies a charging current to a gate of the switching element to turn on the switching element, a charging capability increase transistor connected in parallel with the turn-on output transistor, and a timer circuit connected to the charging capability increase transistor, and being configured to turn on the charging capability increase transistor when the turn-on output transistor is turned on, and to turn off the charging capability increase transistor a prescribed time after the charging capability increase transistor is turned on.

### CROSS-REFERENCE TO RELATED APPLICATION

This application is based upon and claims the benefit of priority of the prior Japanese Patent Application No. 2019-005783, filed on Jan. 17, 2019, the entire contents of which are incorporated herein by reference.

### BACKGROUND OF THE INVENTION

### 1. Field of the Invention

The embodiment discussed herein is related to a switching element drive device which drives a power switching element.

### 2. Background of the Related Art

With power converters which control a load such as a motor, an intelligent power module (IPM) is used. With this IPM, a power switching element which exercises switching control of a load and a drive device which controls and protects the switching element are housed in one package. Usually an insulated gate bipolar transistor (IGBT) is used as a power switching element. Furthermore, a metal-oxide-semiconductor field-effect transistor (MOSFET) is also used as a switching element. Such a switching element is driven by a drive device which is produced as an integrated circuit. An IGBT or a MOSFET is an insulated gate switching element. Therefore, an IGBT or a MOSFET is turned on by driving a gate so as to charge a gate capacitor, and is turned off by discharging electric charges charged.

It is known that there is a trade-off relationship at the time of the switching operation of such a switching element between the magnitude of switching loss and the magnitude of electromagnetic noise generated by the switching element. That is to say, if charge and discharge speeds of a gate capacitor are increased in order to reduce switching loss, then electromagnetic noise increases. If charge and discharge speeds of a gate capacitor are decreased in order to reduce electromagnetic noise, then switching loss increases. Furthermore, if charge and discharge speeds of a gate capacitor are decreased, then switching time lengthens as a matter of course. This needs a change in design including the characteristics of a switching element chip driven and the like.

Therefore, with a drive device of this type of switching element, it is hoped that a reduction in switching loss and a reduction in electromagnetic noise are both realized at the time of switching operation.

On the other hand, switching gate drive capability at the time of turning on or off a switching element is proposed (see, for example, Japanese Laid-open Patent Publication No. 2012-147492). According to Japanese Laid-open Patent Publication No. 2012-147492, for example, an output voltage of a drive device for charging and discharging a gate is decreased at determined timing in a Miller plateau of a gate voltage. Electromagnetic noise is suppressed by lowering the capability to drive a switching element.

With Japanese Laid-open Patent Publication No. 2012-147492, for example, the capability to drive the switching element remains low for a period from when the capability to drive the switching element is lowered to when the switching of the switching element turned on or off ends completely. As a result, switching time of the switching element increases. That is to say, a reduction in switching time and a reduction in electromagnetic noise are not both realized.

### SUMMARY OF THE INVENTION

According to an aspect, there is provided a drive device for driving a switching element, including: a turn-on output transistor connected to a gate of the switching element, the turn-on output transistor supplying a charging current to the gate of the switching element to turn on the switching element; a charging capability increase transistor connected in parallel with the turn-on output transistor; and a timer circuit connected to the charging capability increase transistor, and being configured to turn on the charging capability increase transistor when the turn-on output transistor is turned on, and to turn off the charging capability increase transistor a prescribed time after the charging capability increase transistor is turned on.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 illustrates a switching element drive device according to an embodiment;

FIG. 2 is a circuit diagram illustrative of a concrete example of the structure of the drive device;

FIG. 3 illustrates waveforms at notable portions of a charging circuit and a charging capability increase circuit; and

FIG. 4 is a waveform diagram illustrative of a change in switching element relative to an input signal.

### DETAILED DESCRIPTION OF THE INVENTION

An embodiment will now be described in detail with reference to the accompanying drawings. In the accompanying drawings components marked with the same numerals are the same components.

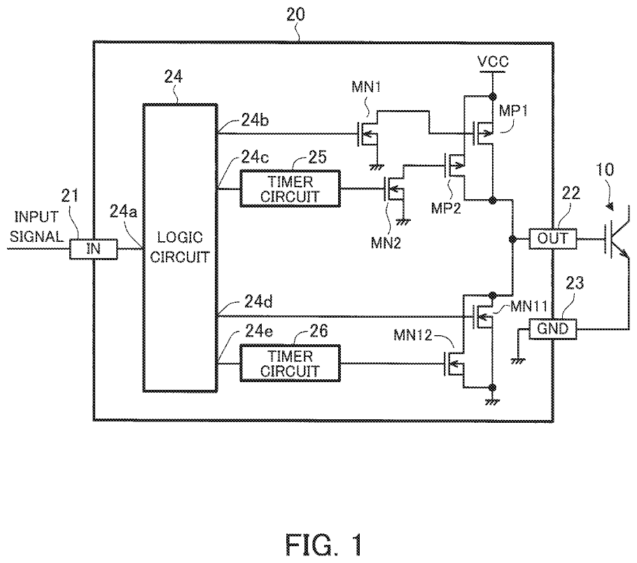

FIG. 1 illustrates a switching element drive device according to an embodiment.

A switching element 10 and a drive device 20 which drives the switching element 10 are illustrated in FIG. 1. In the example of FIG. 1, an IGBT is used as the switching element 10. The switching element 10 and the drive device 20 illustrated in FIG. 1 may be applied to, for example, an IPM which drives a three-phase motor. In this case, the switching element 10 is a high-side or low-side power switching element of a totem-pole circuit which is an output circuit for each phase, and the drive device 20 is a drive circuit which drives each of these power switching elements.

The drive device 20 includes an input terminal 21, an output terminal 22, and a ground terminal 23. The input terminal 21 inputs an input signal by which the switching element 10 is turned on or off. The output terminal 22 is connected to the gate of the switching element 10. The ground terminal 23 is connected to an emitter of the switching element 10.

The input terminal 21 is connected to a signal input 24a of a logic circuit 24. Furthermore, the logic circuit 24 includes a turn-on signal output 24b, a charging capability increase signal output 24c, a turn-off signal output 24d, and a discharging capability increase signal output 24e.

The turn-on signal output 24b is connected to the gate of an n-channel MOSFET (hereinafter referred to as the NMOS transistor) MN1 and the drain of the NMOS transistor MN1 is connected to the gate of a p-channel MOSFET (hereinafter referred to as the PMOS transistor) MP1. The source of the NMOS transistor MN1 is connected to ground. The source of the PMOS transistor MP1 is connected to a power supply VCC. The drain of the PMOS transistor MP1 is connected to the output terminal 22. The PMOS transistor MP1 is a turn-on output transistor which supplies a charging current to the switching element 10 at the time of turning on the switching element 10.

The charging capability increase signal output 24c is connected to an input of a timer circuit 25. The output of the timer circuit 25 is connected to the gate of an NMOS transistor MN2. The drain of the NMOS transistor MN2 is connected to the gate of a PMOS transistor MP2. The source of the NMOS transistor MN2 is connected to the ground. The source of the PMOS transistor MP2 is connected to the power supply VCC. The drain of the PMOS transistor MP2 is connected to the output terminal 22. The PMOS transistor MP2 connected in parallel with the PMOS transistor MP1 functions as a charging capability increase transistor.

The turn-off signal output 24d is connected to the gate of an NMOS transistor MN11. The drain of the NMOS transistor MN11 is connected to the output terminal 22. The source of the NMOS transistor MN11 is connected to the ground.

The discharging capability increase signal output 24e is connected to an input of a timer circuit 26. The output of the timer circuit 26 is connected to the gate of an NMOS transistor MN12. The drain of the NMOS transistor MN12 is connected to the output terminal 22. The source of the NMOS transistor MN12 is connected to the ground. The NMOS transistor MN11 is a turn-off output transistor which sinks a discharging current from the switching element 10 at the time of turning off the switching element 10. Furthermore, the NMOS transistor MN12 connected in parallel with the NMOS transistor MN11 functions as a discharging capability increase transistor.

The NMOS transistor MN1 and the PMOS transistor MP1 are included in a charging circuit which charges a gate capacitor of the switching element 10. The NMOS transistor MN11 is included in a discharging circuit which discharges electric charges stored in the gate capacitor of the switching element 10. Each of the PMOS transistor MP1 and the NMOS transistor MN11 has an on-state resistance value by which target switching characteristics are realized.

The timer circuit 25, the NMOS transistor MN2, and the PMOS transistor MP2 are included in a charging capability increase circuit which temporarily increases the capability to charge the gate capacitor of the switching element 10. The timer circuit 26 and the NMOS transistor MN12 are included in a discharging capability increase circuit which temporarily increases the capability to discharge electric charges stored in the gate capacitor of the switching element 10. Therefore, the PMOS transistor MP2 has an on-state resistance value by which a current corresponding to an increase in the charging capability flows, and the NMOS transistor MN12 has an on-state resistance value by which a current corresponding to an increase in the discharging capability flows.

The timer circuit 25 counts time from when an input signal for turning on the switching element 10 is inputted to the input terminal 21 to just before a gate voltage of the switching element 10 which rises reaches a gate threshold voltage. The timer circuit 26 counts time from when an input signal for turning off the switching element 10 is inputted to the input terminal 21 to just before a gate voltage of the switching element 10 which falls reaches the gate threshold voltage.

On the charging side of the drive device 20 illustrated in FIG. 1, a pull-up resistor (not illustrated) is connected between the drain of the NMOS transistor MN1 and the power supply VCC and a pull-up resistor (not illustrated) is connected between the drain of the NMOS transistor MN2 and the power supply VCC.

When an input signal for turning on the switching element 10 is inputted to the input terminal 21 of the drive device 20 having the above structure, the logic circuit 24 outputs a turn-on signal to the turn-on signal output 24b and outputs a charging capability increase signal to the charging capability increase signal output 24c. As a result, the NMOS transistor MN1 and the PMOS transistor MP1 are turned on and a charging current is supplied to the gate capacitor of the switching element 10. Furthermore, the timer circuit 25 which receives the charging capability increase signal turns on the NMOS transistor MN2 and the PMOS transistor MP2 to supply an additional charging current to the gate capacitor of the switching element 10. As a result, the capability to charge the gate capacitor of the switching element 10 is increased by the charging current supplied by the PMOS transistor MP2 disposed in parallel with the PMOS transistor MP1, and the switching element 10 is driven at a high speed.

After prescribed time elapses and timing ends, the timer circuit 25 turns off each of the NMOS transistor MN2 and the PMOS transistor MP2. Accordingly, the gate capacitor of the switching element 10 is charged only by the PMOS transistor MP1. At this time the NMOS transistors MN11 and MN12 are turned off by the logic circuit 24.

When the drive device 20 turns on the switching element 10, the drive device 20 increases the charging capability in this way only just after charging the gate capacitor is begun. As a result, switching time of the switching element 10 is reduced and switching loss is reduced. The charging capability is decreased after the elapse of the prescribed time. Accordingly, electromagnetic noise is reduced.

Next, when an input signal for turning off the switching element 10 is inputted to the input terminal 21, the logic circuit 24 outputs a turn-off signal to the turn-off signal output 24d and outputs a discharging capability increase signal to the discharging capability increase signal output 24e. By doing so, the NMOS transistor MN11 is turned on to discharge electric charges stored in the gate capacitor of the switching element 10. Furthermore, the timer circuit 26 which receives the discharging capability increase signal turns on the NMOS transistor MN12 so that the NMOS transistor MN12 will sink an additional discharging current from the gate capacitor of the switching element 10. As a result, the capability to discharge electric charges stored in the gate capacitor of the switching element 10 is increased by the discharging current sunk by the NMOS transistor MN12 disposed in parallel with the NMOS transistor MN11, and the switching element 10 is driven at a high speed.

After prescribed time elapses and timing ends, the timer circuit 26 turns off the NMOS transistor MN12. Accordingly, electric charges stored in the gate capacitor of the switching element 10 are discharged only by the NMOS transistor MN11. At this time the NMOS transistors MN1 and MN2 and the PMOS transistors MP1 and MP2 are turned off by the logic circuit 24.

When the drive device 20 turns off the switching element 10, the drive device 20 increases the discharging capability in this way only just after discharging electric charges stored in the gate capacitor is begun. As a result, switching time of the switching element 10 is reduced and switching loss is reduced. The discharging capability is decreased after the elapse of the prescribed time. Accordingly, electromagnetic noise is reduced.

Concrete examples of the logic circuit 24 and the timer circuits 25 and 26 included in the drive device 20 will now be described.

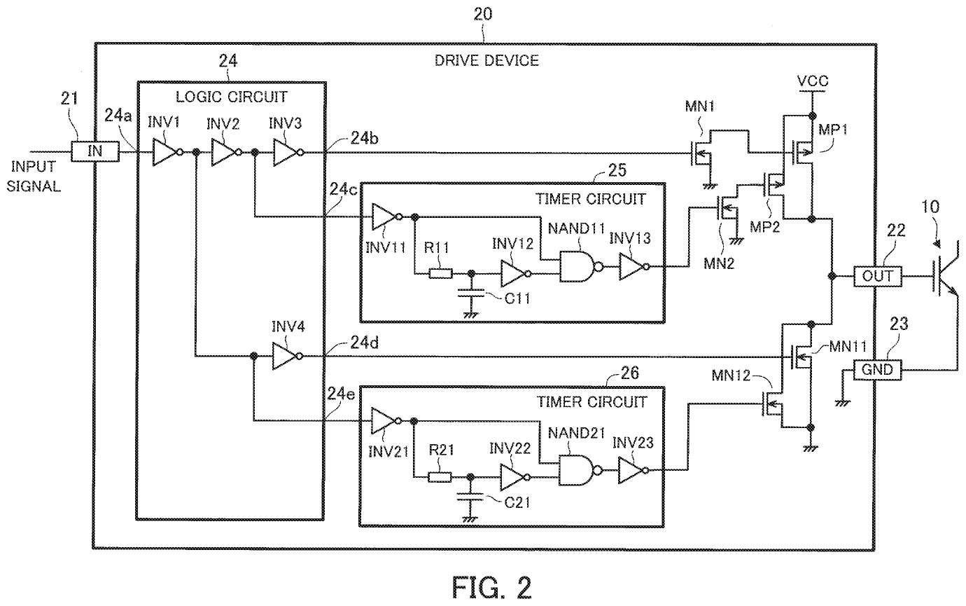

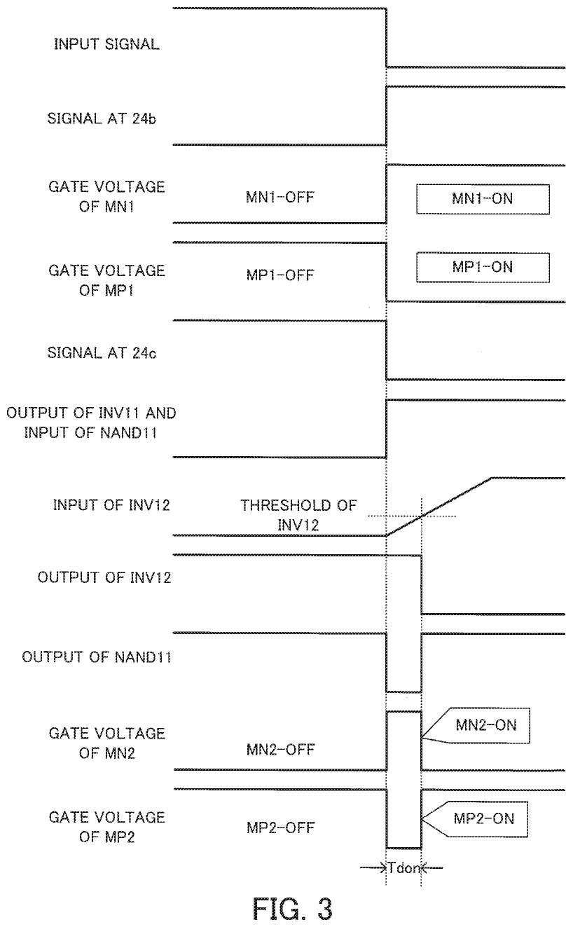

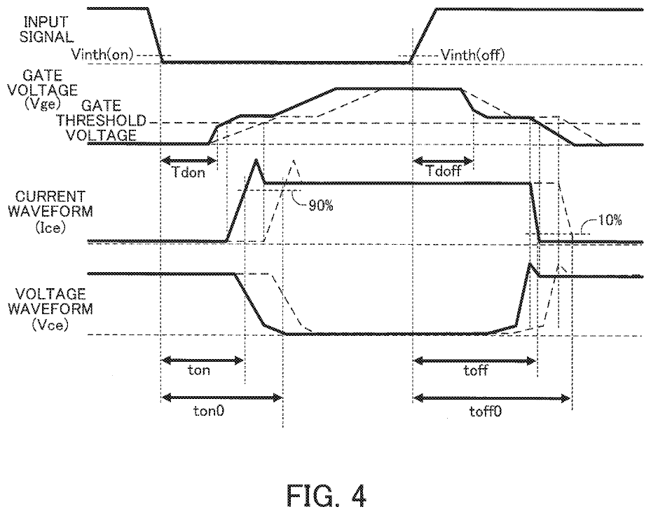

FIG. 2 is a circuit diagram illustrative of a concrete example of the structure of the drive device. FIG. 3 illustrates waveforms at notable portions of the charging circuit and the charging capability increase circuit. FIG. 4 is a waveform diagram illustrative of a change in the switching element relative to an input signal. Components in FIG. 2 which are the same as those illustrated in FIG. 1 are marked with the same numerals and detailed descriptions of them will be omitted.

The logic circuit 24 of the drive device 20 includes inverter circuits INV1, INV2, INV3, and INV4. An input of the inverter circuit INV1 is connected to the input terminal 21. An output of the inverter circuit INV1 is connected to an input of the inverter circuit INV2, an input of the inverter circuit INV4, and the discharging capability increase signal output 24e. An output of the inverter circuit INV2 is connected to an input of the inverter circuit INV3 and the charging capability increase signal output 24c. An output of the inverter circuit INV3 is connected to the turn-on signal output 24b. An output of the inverter circuit INV4 is connected to the turn-off signal output 24d.

The timer circuit 25 includes an inverter circuit INV11 whose input is connected to the charging capability increase signal output 24c. An output of the inverter circuit INV11 is connected to one input of a two-input NAND circuit NAND11 (hereinafter referred to as the NAND circuit NAND11) and one terminal of a resistor R11. The other terminal of the resistor R11 is connected to one terminal of a capacitor C11 and an input of an inverter circuit INV12. The other terminal of the capacitor C11 is connected to the ground. An output of the inverter circuit INV12 is connected to the other input of the NAND circuit NAND11. An output of the NAND circuit NAND11 is connected to an input of an inverter circuit INV13. An output of the inverter circuit INV13 is an output of the timer circuit 25 and is connected to the gate of the NMOS transistor MN2.

The timer circuit 26 includes an inverter circuit INV21 whose input is connected to the discharging capability increase signal output 24e. An output of the inverter circuit INV21 is connected to one input of a two-input NAND circuit NAND21 (hereinafter referred to as the NAND circuit NAND21) and one terminal of a resistor R21. The other terminal of the resistor R21 is connected to one terminal of a capacitor C21 and an input of an inverter circuit INV22. The other terminal of the capacitor C21 is connected to the ground. An output of the inverter circuit INV22 is connected to the other input of the NAND circuit NAND21. An output of the NAND circuit NAND21 is connected to an input of an inverter circuit INV23. An output of the inverter circuit INV23 is an output of the timer circuit 26 and is connected to the gate of the NMOS transistor MN12.

The operation of the drive device 20 for the switching element 10 will now be described.

First, when an input signal by which the switching element 10 is turned off is inputted, the input signal is a high(H)-level logical signal as illustrated in FIG. 3. At this time the H-level input signal is inputted to the logic circuit 24. The logic circuit 24 outputs a low(L)-level signal to the turn-on signal output 24b via the inverter circuits INV1, INV2, and INV3 at the three stages. This L-level signal becomes a gate voltage of the NMOS transistor MN1. As a result, the NMOS transistor MN1 is turned off and the PMOS transistor MP1 is also turned off.

On the other hand, the logic circuit 24 outputs an H-level signal to the charging capability increase signal output 24c. This H-level signal is inputted to the inverter circuit INV11 of the timer circuit 25. Accordingly, the inverter circuit INV11 outputs an L-level signal. This L-level signal is inputted to one input of the NAND circuit NAND11. As a result, the NAND circuit NAND11 outputs an H-level signal regardless of the logic state of the other input and inputs the H-level signal to the inverter circuit INV13. At this time the inverter circuit INV13 outputs an L-level signal. This L-level signal becomes a gate voltage of the NMOS transistor MN2. As a result, the NMOS transistor MN2 is turned off and the PMOS transistor MP2 is also turned off.

Furthermore, when the H-level input signal by which the switching element 10 is turned off is inputted, the logic circuit 24 outputs an H-level signal to the turn-off signal output 24d. This H-level signal becomes a gate voltage of the NMOS transistor MN11. As a result, the NMOS transistor MN11 is turned on and continues to discharge electric charges stored in the gate capacitor of the switching element 10.

On the other hand, the logic circuit 24 outputs an L-level signal to the discharging capability increase signal output 24e. This L-level signal is inputted to the inverter circuit INV21 of the timer circuit 26. Accordingly, the inverter circuit INV21 outputs an H-level signal. This H-level signal sufficiently charges the capacitor C21 via the resistor R21. As a result, the inverter circuit INV22 inputs an H-level signal and outputs an L-level signal. This L-level signal is inputted to the other input of the NAND circuit NAND21. Accordingly, the NAND circuit NAND21 outputs an H-level signal. This H-level signal is inputted to the inverter circuit INV23. As a result, the inverter circuit INV23 outputs an L-level signal. This L-level signal becomes a gate voltage of the NMOS transistor MN12. Accordingly, the NMOS transistor MN12 is turned off.

Next, when an input signal by which the switching element 10 is turned on is inputted, the input signal switches to an L-level logical signal. As a result, the L-level input signal is inputted to the logic circuit 24. The logic circuit 24 outputs an H-level signal to the turn-on signal output 24b via the inverter circuits INV1, INV2, and INV3 at the three stages. This H-level signal becomes a gate voltage of the NMOS transistor MN1. As a result, the NMOS transistor MN1 is turned on and the PMOS transistor MP1 is also turned on. When the PMOS transistor MP1 is turned on, a charging current is supplied from the power supply VCC to the switching element 10 via the PMOS transistor MP1.

At this time the logic circuit 24 outputs an L-level signal to the charging capability increase signal output 24c. This L-level signal is inputted to the inverter circuit INV11 of the timer circuit 25. Accordingly, the inverter circuit INV11 outputs an H-level signal. This H-level signal is inputted to the one input of the NAND circuit NAND11 and is inputted to the capacitor C11 via the resistor R11. At this time charging the capacitor C11 is begun in the state in which the capacitor C11 is sufficiently discharged. As a result, a voltage inputted to the inverter circuit INV12 changes so as to rise from a ground potential. Therefore, when charging the capacitor C11 is begun, the inverter circuit INV12 outputs an H-level signal. At this time both inputs of the NAND circuit NAND11 become an H level. As a result, the NAND circuit NAND11 outputs an L-level signal. The inverter circuit INV13 outputs an H-level signal. This H-level signal becomes a gate voltage of the NMOS transistor MN2. Accordingly, the NMOS transistor MN2 is turned on and the PMOS transistor MP2 is also turned on. Because the PMOS transistor MP2 is turned on, an additional charging current is supplied from the power supply VCC to the switching element 10 via the PMOS transistor MP2.

The PMOS transistors MP1 and MP2 are turned on in this way. As a result, a large charging current is supplied from the power supply VCC to the switching element 10 via the PMOS transistors MP1 and MP2 and the gate capacitor of the switching element 10 is charged at a high speed.

When prescribed time Tdon elapses after charging the capacitor C11 is begun, a voltage of the capacitor C11 which rises exceeds the threshold of the inverter circuit INV12. At this time the inverter circuit INV12 outputs an L-level signal. This L-level signal is inputted to the other input of the NAND circuit NAND11. Accordingly, the NAND circuit NAND11 outputs an H-level signal. This H-level signal is inputted to the inverter circuit INV13. At this time the inverter circuit INV13 outputs an L-level signal. This L-level signal becomes a gate voltage of the NMOS transistor MN2. Accordingly, the NMOS transistor MN2 is turned off and the PMOS transistor MP2 is also turned off. As a result, the supply of the additional charging current ends.

That is to say, when an input signal by which the switching element 10 is turned on is inputted to the drive device 20, first the gate capacitor of the switching element 10 is charged at a high speed by the PMOS transistors MP1 and MP2. Next, after the prescribed time Tdon which depends on the time constant of the resistor R11 and the capacitor C11 of the timer circuit 25 elapses, the gate capacitor of the switching element 10 is charged only by the PMOS transistor MP1.

Furthermore, when an L-level input signal by which the switching element 10 is turned on is inputted to the drive device 20, the logic circuit 24 outputs an L-level signal to the turn-off signal output 24d. This L-level signal becomes a gate voltage of the NMOS transistor MN11. As a result, the NMOS transistor MN11 is turned off.

In addition, the logic circuit 24 outputs an H-level signal to the discharging capability increase signal output 24e. This H-level signal is inputted to the inverter circuit INV21 of the timer circuit 26. The inverter circuit INV21 outputs an L-level signal. This L-level signal is inputted to the one input of the NAND circuit NAND21. Accordingly, the NAND circuit NAND21 outputs an H-level signal. This H-level signal is inputted to the inverter circuit INV23. As a result, the inverter circuit INV23 outputs an L-level signal. This L-level signal becomes a gate voltage of the NMOS transistor MN12. Accordingly, the NMOS transistor MN12 is turned off.

As stated above, when an H-level input signal by which the switching element 10 is turned off is inputted to the drive device 20, first the PMOS transistors MP1 and MP2 are turned off and the NMOS transistors MN11 and MN12 are turned on. Next, after prescribed time Tdoff which depends on the time constant of the resistor R21 and the capacitor C21 of the timer circuit 26 elapses, the NMOS transistor MN12 is turned off. Electric charges stored in the gate capacitor of the switching element 10 are discharged only by the NMOS transistor MN11.

More detailed operation of the switching element 10 at the time of the charging and discharging operation of the drive device 20 will now be described with reference to FIG. 4. In FIG. 4, each solid line indicates a waveform obtained in the case where high-speed charging and discharging according to the embodiment is performed and each broken line indicates a waveform obtained in the case where high-speed charging and discharging according to the embodiment is not performed.

As illustrated in FIG. 4, first it is assumed that when an H-level input signal by which the switching element 10 is turned off is being inputted, the input signal switches to an L level. When the level of the input signal which drops falls below a threshold Vinth(on) of the inverter circuit INV1 of the logic circuit 24, the switching element 10 begins turn-on operation. At this time the gate capacitor of the switching element 10 is charged at a high speed. Accordingly, the slope of the rising of a gate voltage Vge is steep.

After prescribed time Tdon which depends on the timer circuit 25 elapses, the gate capacitor of the switching element 10 is charged at a normal speed. Accordingly, the slope of the rising of the gate voltage Vge becomes gentle. The prescribed time Tdon is set to time from when the input signal switches to the L level to just before the gate voltage Vge which rises reaches a gate threshold voltage. The reason for setting a high-speed charging period by time is as follows. There is variation in the gate threshold voltage of the switching element 10 and it is difficult to detect a voltage just before reaching the gate threshold voltage. As a result, circuit structure becomes complex.

When after that the gate voltage Vge of the switching element 10 exceeds the gate threshold voltage, a collector current Ice begins to flow. As a result, a collector-emitter voltage Vce begins to fall. After that the gate voltage Vge becomes a constant value in a Miller plateau in which a gate-collector capacitor of the switching element 10 is charged. After the gate voltage Vge passes the Miller plateau, the gate voltage Vge changes so as to rise to the voltage of the power supply VCC of the drive device 20.

Turn-on time ton for which the switching element 10 is turned on is time from when the level of the input signal falls below the threshold Vinth(on) to when the collector current Ice reaches 90 percent of an on-time current. A comparison between the turn-on time ton and turn-on time ton0 obtained in the case where high-speed charging is not performed at the time of the switching element 10 being turned on indicates that switching time is reduced. A reduction in the switching time leads to a reduction in switching loss. After the prescribed time Tdon elapses, charging is performed at a normal speed. Accordingly, electromagnetic noise does not increase.

Next, it is assumed that when an L-level input signal by which the switching element 10 is turned on is being inputted, the input signal switches to an H level. When the level of the input signal which rises exceeds a threshold Vinth(off) of the inverter circuit INV1 of the logic circuit 24, the switching element 10 begins turn-off operation. At this time the gate capacitor of the switching element 10 is discharged at a high speed. Accordingly, the slope of the falling of the gate voltage Vge is steep.

After prescribed time Tdoff which depends on the timer circuit 26 elapses, the gate capacitor of the switching element 10 is discharged at a normal speed. Accordingly, the slope of the falling of the gate voltage Vge becomes gentle. The prescribed time Tdoff is set to time from when the input signal switches to the H level to before the gate voltage Vge which falls enters the Miller plateau or before the gate voltage Vge which falls reaches the gate threshold voltage. In this embodiment the prescribed time Tdoff is set to time from when the input signal switches to the H level to before the gate voltage Vge which falls enters the Miller plateau.

After that the gate voltage Vge of the switching element 10 falls at a slope at the time of normal discharging. The gate voltage Vge becomes a constant value in the Miller plateau. After the gate voltage Vge passes the Miller plateau, the collector current Ice decreases and the collector-emitter voltage Vce begins to rise.

Turn-off time toff for which the switching element 10 is turned off is time from when the level of the input signal exceeds the threshold Vinth(off) to when the collector current Ice reaches 10 percent of the on-time current. A comparison between the turn-off time toff and turn-off time toff0 obtained in the case where high-speed discharging is not performed at the time of the switching element 10 being turned off indicates that switching time is reduced. A reduction in the switching time leads to a reduction in switching loss. After the prescribed time Tdoff elapses, discharging is performed at a normal speed. Accordingly, electromagnetic noise does not increase.

In the above embodiment, high-speed charging is performed at the time of the switching element 10 being turned on and high-speed discharging is performed at the time of the switching element 10 being turned off. However, one of the high-speed charging and the high-speed discharging may be performed at need.

Furthermore, high-speed charging ends before the gate voltage Vge reaches the gate threshold voltage and high-speed discharging ends before the gate voltage Vge enters the Miller plateau. Because the high-speed charging and the high-speed discharging end before the switching operation, or turn-on and turn-off, of the switching element 10 is begun, the function of the high-speed charging and discharging is easily added to a drive device and a switching element which are already designed without changing the design.

With the drive device for a switching element having the above structure, charging and discharging capability is increased for prescribed time at the time of beginning charging and discharging of the switching element. By doing so, switching time of the switching element is reduced and switching loss is reduced. Furthermore, charging and discharging capability is decreased after the elapse of the prescribed time. As a result, electromagnetic noise is reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A drive device for driving a switching element, comprising:
a turn-on output transistor connected to a gate of the switching element, the turn-on output transistor supplying a charging current to the gate of the switching element to turn on the switching element;
a charging capability increase transistor connected in parallel with the turn-on output transistor; and
a timer circuit connected to the charging capability increase transistor, and being configured to turn on the charging capability increase transistor when the turn-on output transistor is turned on, and to turn off the charging capability increase transistor a prescribed time after the charging capability increase transistor is turned on.

2. The drive device for the switching element according to claim 1, wherein the prescribed time is a time period between a first time when a signal for turning on the switching element is inputted and a second time that is immediately before a gate voltage of the switching element reaches a gate threshold voltage of the switching element.

3. The drive device for the switching element according to claim 1, wherein
the timer circuit includes:
a resistor and a capacitor connected in series, and
a logic circuit having an input thereof connected to a connection of the resistor and the capacitor; and
the prescribed time is set to be a time period between a first time when charging of the capacitor via the resistor begins and a second time when a voltage of the capacitor reaches a threshold of the logic circuit, at a time of a signal for turning on the switching element being inputted.

4. A drive device for driving a switching element, comprising:
a turn-off output transistor connected to a gate of the switching element, for sinking a discharging current from the gate of the switching element to turn off the switching element;
a discharging capability increase transistor connected in parallel with the turn-off output transistor; and
a timer circuit connected to the discharging capability increase transistor, the timer circuit being configured to turn on the discharging capability increase transistor when the turn-off output transistor is turned on, and to turn off the discharging capability increase transistor a prescribed time after the discharging capability increase transistor is turned on.

5. The drive device for the switching element according to claim 4, wherein the prescribed time is a time period between a first time when a signal for turning off the switching element is inputted and a second time immediately before a gate voltage of the switching element reaches a gate threshold voltage of the switching element.

6. The drive device for the switching element according to claim 4, wherein the prescribed time is a time period between a first time when a signal for turning off the switching element is inputted and a second time immediately before a gate voltage of the switching element enters a Miller plateau of the switching element.

7. The drive device for the switching element according to claim 4, wherein:
the timer circuit includes:
a resistor and a capacitor connected in series; and
a logic circuit having an input thereof connected to a connection of the resistor and the capacitor; and
the prescribed time is set to be a time period between a first time when charging of the capacitor via the resistor begins and a second time when a voltage of the capacitor reaches a threshold of the logic circuit, at a time of a signal for turning off the switching element being inputted.
